(19) United States
(12) Patent Application Publication
(10) Pub. No.: US 2016/0197211 A1
(43) Pub. Date: Jul. 7, 2016

(54) METHOD OF MANUFACTURING A PHOTOELECTRIC AND THERMOELECTRIC SENSOR, AND PHOTOELECTRIC AND THERMOELECTRIC SENSOR

(71) Applicant: National Chi Nan University, Puli (TW)

(72) Inventors: Kuei-Sen HSIAO, Puli (TW); Chao-Yang TSAI, Puli (TW); Sheng-Lin CHENG, Puli (TW); Chin-Kai CHANG, Puli (TW)

(21) Appl. No.: 14/818,381

(22) Filed: Aug. 5, 2015

(30) Foreign Application Priority Data
Jan. 7, 2015 (TW) 104100385

(51) Int. Cl. H01L 31/0224; H01L 35/08; H01L 35/34; H01L 31/18

(52) U.S. Cl. CPC H01L 31/022491; H01L 31/1804; H01L 35/08; H01L 35/34

(57) ABSTRACT

A method of manufacturing a photoelectric and thermoelectric sensor includes the steps of: preparing a silicon substrate and an etching solution that includes hydrofluoric acid, isopropyl alcohol and deionized water; performing electrochemical etching on the silicon substrate in the etching solution to obtain a porous silicon substrate; and forming on the porous silicon substrate an electrode unit that is connected to the porous silicon substrate and that is adapted for being connected to an external circuit.

### CROSS-REFERENCE TO RELATED APPLICATION

This application claims priority of Taiwanese Patent Application No. 104100385, filed on Jan. 7, 2015.

### FIELD

The disclosure relates to a method of a manufacturing a photoelectric and thermoelectric sensor, and a photoelectric and thermoelectric sensor.

### BACKGROUND

A conventional thermoelectric device includes at least one thermoelectric unit including a P-type semiconductor element and a N-type semiconductor element connected to the P-type semiconductor element. When a temperature difference is present between the P-type and N-type semiconductor elements, current flow is generated in the conventional thermoelectric device. FIGS. 1 and 2 illustrate consecutive steps of manufacturing a conventional thermoelectric device. In FIG. 1, a first module 71 is obtained by forming a plurality of thermally conductive members 74 and a plurality of first thermoelectric members 710 on a second substrate 711 and a first substrate 712. Then, as shown in FIG. 2, a second module 72 is obtained by forming a plurality of second thermoelectric members 720 between a third substrate 722 and a fourth substrate 721. Each of the first and second thermoelectric members 710, 720 includes a P-type semiconductor element and a N-type semiconductor element. After the second module 72 is stacked on the first module 71, the P-type and N-type semiconductor elements in each of the first and second thermoelectric members 710, 720 are electrically connected to each other to obtain the conventional thermoelectric device.

Manufacture of the conventional thermoelectric device is complicated, time-consuming and costly.

### SUMMARY

Therefore, an object of the disclosure is to provide a method of manufacturing a photoelectric and thermoelectric sensor, and a photoelectric and thermoelectric sensor made therefrom, that can alleviate at least one of the drawbacks associated with the conventional thermoelectric device.

According to a first aspect of the present disclosure, a method of manufacturing a photoelectric and thermoelectric sensor includes the steps of:
preparing a silicon substrate and an etching solution that includes hydrofluoric acid, isopropyl alcohol and deionized water;
performing electrochemical etching of the silicon substrate in the etching solution to obtain a porous silicon substrate; and
forming on the porous silicon substrate an electrode unit that is connected to the porous silicon substrate and that is adapted for being connected to an external circuit.

According to a second aspect of the present disclosure, a photoelectric and thermoelectric sensor includes a porous silicon substrate and an electrode unit. The electrode unit is disposed on and connected to the porous silicon substrate, and is adapted for being connected to an external circuit.

### BRIEF DESCRIPTION OF THE DRAWINGS

Other features and advantages of the present disclosure will become apparent in the following detailed description of the embodiments with reference to the accompanying drawings, of which:

FIGS. 1 and 2 illustrate consecutive steps of manufacturing a conventional thermoelectric device;

FIG. 3 is a flow chart that illustrates the embodiment of a method of manufacturing a photoelectric and thermoelectric sensor of the present disclosure;

FIG. 4 is a top view of a first embodiment of a photoelectric and thermoelectric sensor of the present disclosure;

FIG. 5 is a top view of a second embodiment of the photoelectric and thermoelectric sensor of the present disclosure;

FIG. 6 is a schematic and partly cross-sectional view of an electrochemical etching apparatus used for manufacturing the photoelectric and thermoelectric sensor of the present disclosure; and

FIG. 7 is a top view showing the photoelectric and thermoelectric sensor of the present disclosure connected to an ammeter.

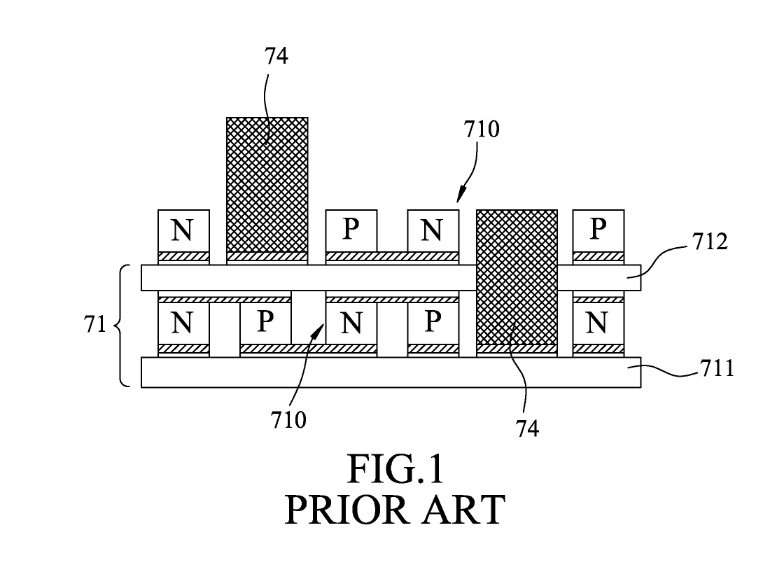

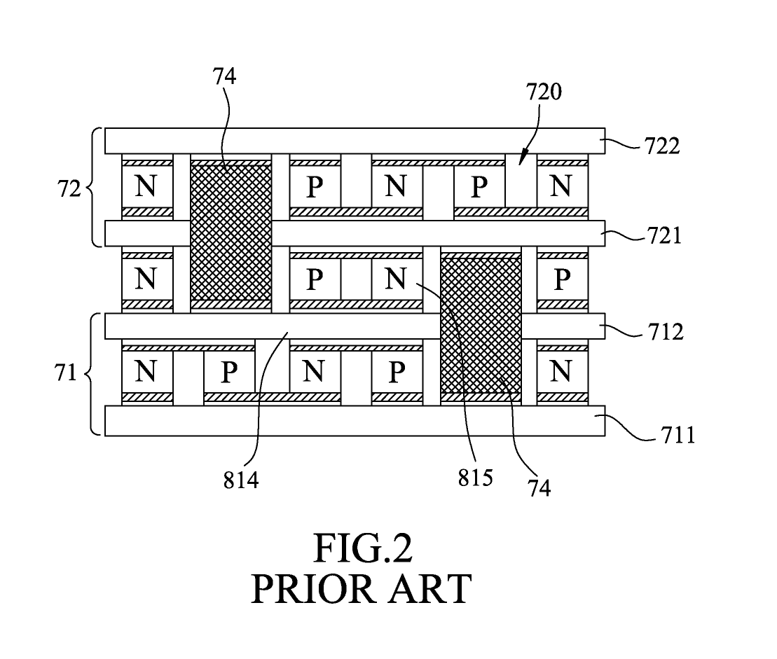

### DETAILED DESCRIPTION

Before the present disclosure is described in greater detail with reference to the accompanying embodiments, it should be noted herein that like elements are denoted by the same reference numerals throughout the disclosure.

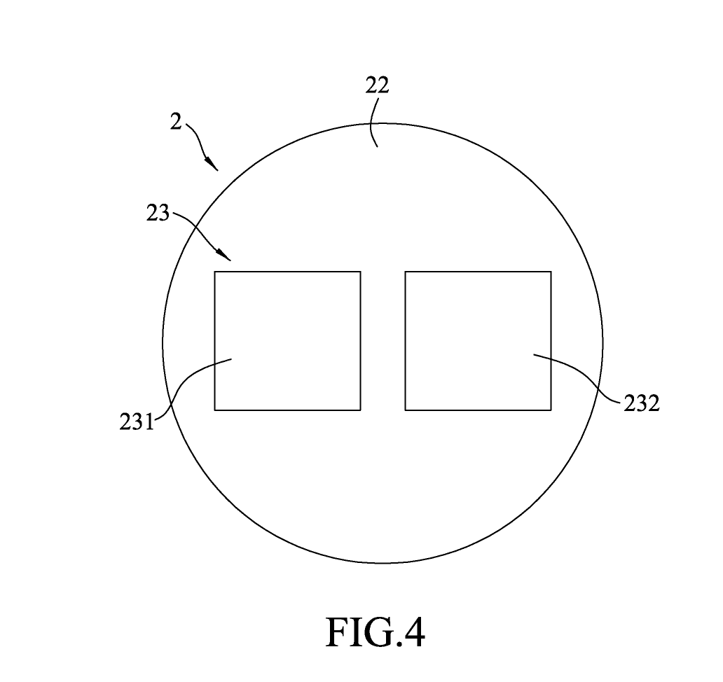

FIG. 4 illustrates a first embodiment of a photoelectric and thermoelectric sensor 2 of the present disclosure. The photoelectric and thermoelectric sensor 2 includes a porous silicon substrate 22 and an electrode unit 23 that is disposed on and connected to the porous silicon substrate 22, and that is adapted for being connected to an external circuit for measuring photoelectric and thermoelectric effects of the sensor 2. The electrode unit 23 includes a first electrode 231 and a second electrode 232 spaced apart from the first electrode 231.

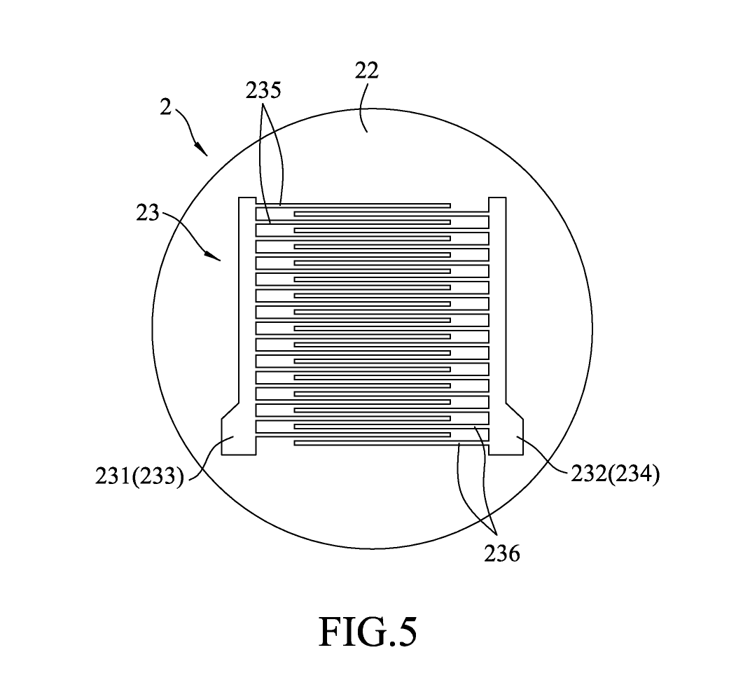

Referring to FIG. 5, in a second embodiment of the photoelectric and thermoelectric sensor 2, the electrode unit 23 may be configured as an interdigitated electrode structure. The first electrode 231 has a first main portion 233 and a plurality of first protruding portions 235 extending from the first main portion 233 toward the second electrode 232. The second electrode 232 has a second main portion 234 spaced apart from the first main portion 233, and a plurality of second protruding portions 236 extending from the second main portion 234 toward the first electrode 231 and alternately disposed with the first protruding portions 235. Therefore, the first and second electrodes 231, 232 are arranged in an interdigitated comb structure.

In order to decrease contact resistance, the electrode unit 23 may be made of gold. The porous silicon substrate 22 may be a p-type silicon substrate. In this embodiment, the porous silicon substrate 22 is a p-type silicon substrate with a thickness of 525±25 μm. A distance between each of the first protruding portions 235 of the first electrode 231 and an adjacent one of the second protruding portions 236 of the second electrode 232 is not greater than 0.6 mm.

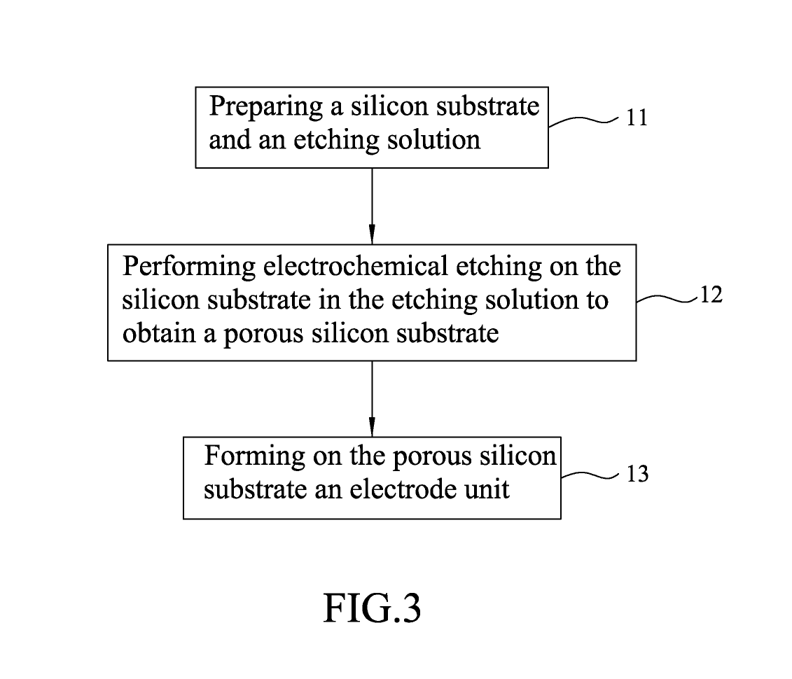

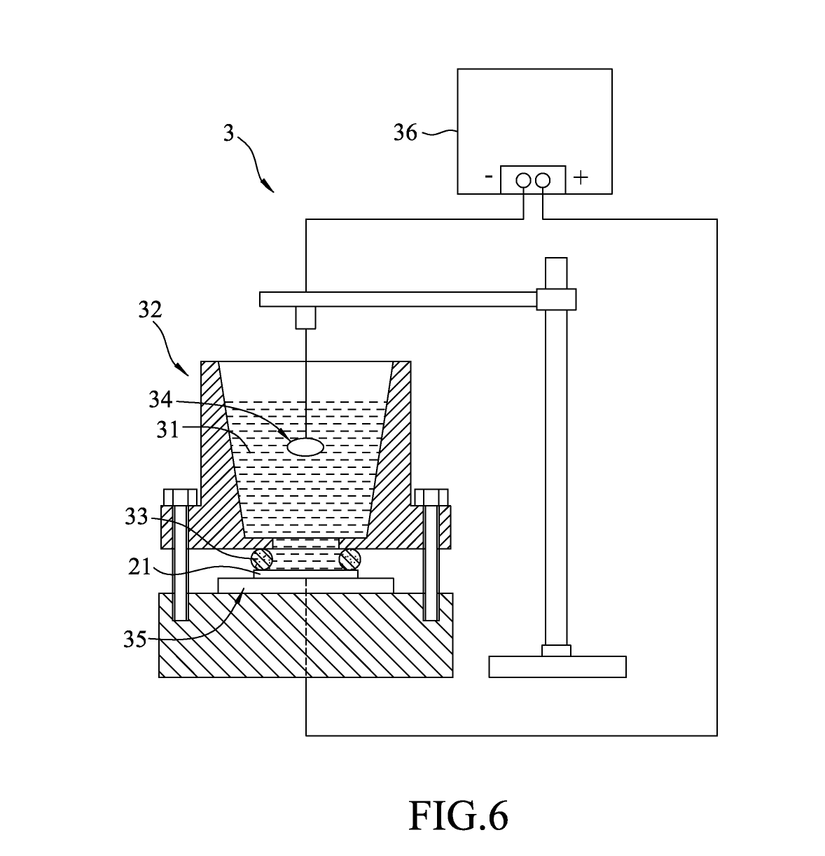

Referring to FIGS. 3 and 6, a method of manufacturing the photoelectric and thermoelectric sensor 2 includes the steps of:
preparing a silicon substrate 21 and an etching solution 31 that includes hydrofluoric acid, isopropyl alcohol and deionized water;
performing electrochemical etching on the silicon substrate 21 in the etching solution to obtain a porous silicon substrate 22; and
forming on the porous silicon substrate 22 the electrode unit 23 that is connected to the porous silicon substrate 22 and that is adapted for being connected to the external circuit.

To be more specific, an electrochemical etching apparatus 3 (see FIG. 6) is used for etching the silicon substrate 21 to obtain the porous silicon substrate 22, and includes a reaction vessel 32 that is for receiving the etching solution 31 and that is formed with a bottom opening, an O-ring 33 that is disposed underneath the bottom opening, a cathode 34, an anode 35 and a power supply 36. The reaction vessel 32 and the O-ring 33 may be made of polytetrafluoroethylene (also known as Teflon), which is resistant to acid, base, corrosion, and is insoluble in and non-reactive with the etching solution 31. The cathode 34 and the anode 35 are made of conductive materials. The cathode 34 may be made of copper, and the anode 35 may be made of platinum.

The silicon substrate 21 is fixed between the anode 35 and the O-ring 33. The O-ring 33 hermetically seals a gap between the silicon substrate 21 and the reaction vessel 32. The etching solution 31 is added into the reaction vessel 32 and the cathode 34 is then dipped into the etching solution 31. The silicon substrate 21 is electrochemically etched under the conditions that the current density of the power supply 36 is 50 mA/cm and the temperature of the etching solution 31 is ranged from 20° C. to 40° C. Note that the current density may be altered according to practical requirements. The electrochemical etching is performed for 20 minutes to 40 minutes. For example, the electrochemical etching may be performed for 20 minutes to 30 minutes. During the electrochemical etching process, a reduction reaction producing hydrogen ions take places at the cathode 34 so as to release hydrogen gas, and an oxidation reaction takes place at the anode 35 such that the silicon substrate 21 contacting the anode 35 is etched to form the porous silicon substrate 22, with pore sizes ranging from 10 nm to 100 nm.

It should be noted that shapes of the pores of the porous silicon substrate 22 may change with the concentration and composition ratio of the etching solution 31. Sizes of the pores are likely to be increased with an increase of the current density of the power supply 36. Therefore, desired pore sizes can be obtained by using desired etching solutions and adjusting the current density. Isopropyl alcohol is used to reduce etching rate and increase etching uniformity to obtain the porous silicon substrate 22 having finer and more evenly distributed pores. A weight ratio of hydrofluoric acid to isopropyl alcohol to deionized water in the etching solution 31 is 1:2:1 or 1:3:1.

Preferably, before etching, the silicon substrate 21 is ultrasonically washed with deionized water, acetone and ethanol in sequence and is then blow-dried with nitrogen.

The electrode unit 23 formed on the porous silicon substrate 22 may be the one shown in FIG. 4 or the one shown in FIG. 5 (i.e., the interdigitated electrode unit 23).

To form the interdigitated electrode unit 23 on the porous silicon substrate 22, thermal evaporation deposition with the use of a shadow mask is used. To be more specific, the shadow mask with a pattern corresponding to the pattern of the interdigitated electrode unit 23 is laminated on the porous silicon substrate 22. Gold is evaporated under vacuum, and is deposited on the porous silicon substrate 22 so as to form the interdigitated electrode unit 23 on the porous silicon substrate 22. The thickness of the interdigitated electrode unit 23 may be 50 nm and can be changed according to practical requirements.

The following examples and comparative examples are provided to illustrate the embodiments of the disclosure, and should not be construed as limiting the scope of the disclosure.

### EXAMPLES

### Example 1 (E1)

A photoelectric and thermoelectric sensor 2 having the structure shown in FIG. 4 was prepared based on the method of the present disclosure under the following conditions. The weight ratio of hydrofluoric acid (HF) to isopropyl alcohol (IPA) to deionized water in the etching solution 31 was 1:3:1. The current density of the power supply 36 was set at 50 mA/cm². The temperature of the etching solution 31 was maintained in the range of 20° C. to 40° C. The electrochemical etching was conducted for 30 minutes. Each of the first and second electrodes 231, 232 had a length of 4 mm and a width of 4 mm. A distance between the first and second electrodes 231, 232 was 1.5 mm.

### Example 2 (E2)

A photoelectric and thermoelectric sensor 2 having the structure shown in FIG. 5 was prepared based on the method of the present disclosure under the following conditions. The weight ratio of hydrofluoric acid to isopropyl alcohol to deionized water in the etching solution 31 was 1:2:1. The current density of the power supply 36 was set at 50 mA/cm². The temperature of the etching solution 31 was maintained in the range of 20° C. to 40° C. The electrochemical etching was conducted for 30 minutes. The electrode unit 23 having a thickness of 0.1 mm was prepared using thermal evaporation deposition. Each of the first and second main portions 233, 234 had a length of 9 mm and a width of 1 mm. Each of the first and second protruding portions 235, 236 had a length of 6 mm and a width of 0.1 mm. The distance between each of the first protruding portions 235 and an adjacent one of the second protruding portions 236 was 0.14 mm.

### Example 3 (E3)

The photoelectric and thermoelectric sensor 2 of Example 3 was similar in structure to that of Example 2, except that the distance between each of the first protruding portions 235 and an adjacent one of the second protruding portions 236 was 0.6 mm.

### Example 4 (E4)

The method for forming the photoelectric and thermoelectric sensor 2 of Example 4 was similar to that of Example 2, except that the weight ratio of hydrofluoric acid to isopropyl alcohol to deionized water in the etching solution 31 was 1:2:1. The structure of the photoelectric and thermoelectric sensor thus obtained was similar to that of Example 2, except that the distance between each of the first protruding portions 235 and an adjacent one of the second protruding portions 236 was 0.6 mm.

### Comparative Example (CE)

The method for forming the photoelectric and thermoelectric sensor of Comparative Example was similar to that of Example 4, except that the etching solution was composed of hydrofluoric acid (HF) and ethanol (EtOH) at a weight ratio of 1:1.

### Determination of Thermoelectric Property

The thermoelectric property of the photoelectric and thermoelectric sensor 2 of Example 2 was determined.

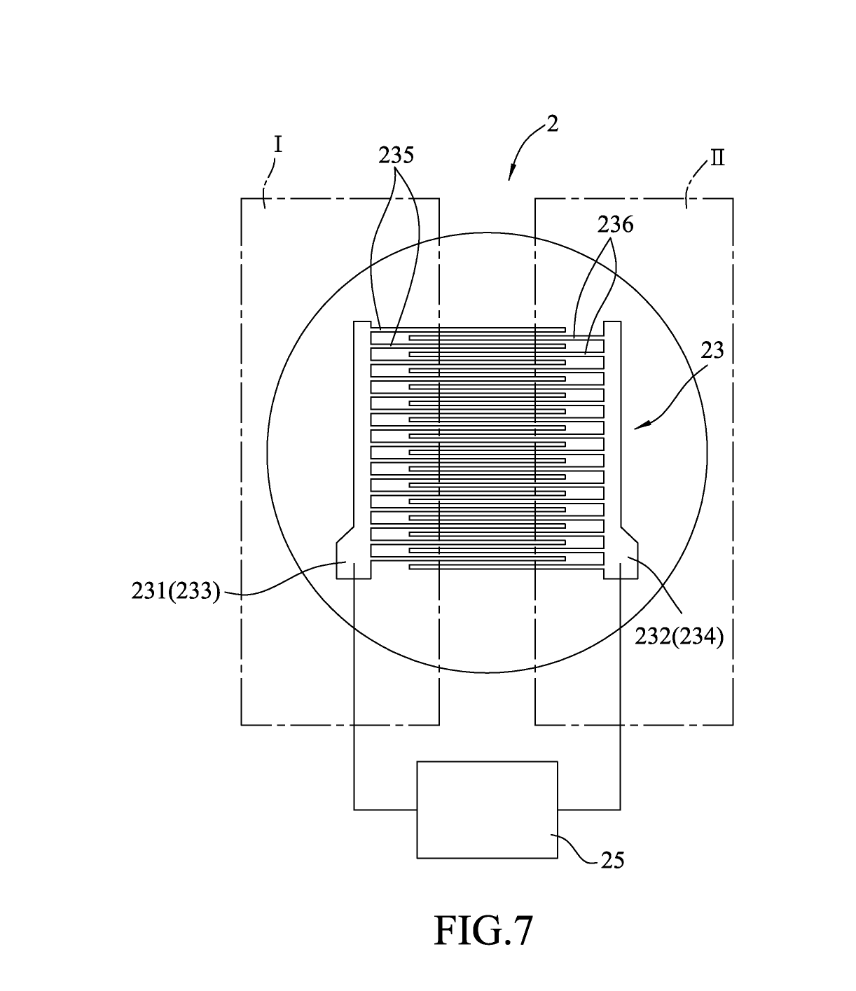

Specifically, referring to FIG. 7, a first region I surrounding the first main portion 233 of the first electrode 231 and part of the first protruding portions 235, and a second region II surrounding the second main portion 234 of the second electrode 232 and part of the second protruding portions 236 were defined. The first and second main portions 233, 234 were connected to an ammeter 25. One of the first and second regions I, II was heated (e.g., the first region I was heated and the second region II was not heated) to measure the current generated by the photoelectric and thermoelectric sensor 2.

During the heating process, temperature differences between the first and second main portions 233, 234, and corresponding current flows were recorded as shown in Table 1.

TABLE 1

| Temperature Difference (° C.) | Current flow (μA) |
|---|---|
| 0 | 0.186 |
| 0.4 | 6.86 |
| 0.6 | 7.50 |

As shown in Table 1, the photoelectric and thermoelectric sensor 2 of E2 is capable of producing current flow in response to the temperature difference between the first and second electrodes 231, 232. The current flow increased with an increase of the temperature difference.

### Determination of Photoelectric Property

Similar to the procedure in Determination Of Thermoelectric Property, in each of the photoelectric and thermoelectric sensor of E1 to E4 and CE, a first region I and a second region II were defined. The first and second electrodes 231, 232 respectively in the first and second regions I, II of the photoelectric and thermoelectric sensor of E1 were connected to an ammeter 25. Similarly, the first and second main portions 233, 234 in each of the photoelectric and thermoelectric sensors of E2 to E4 and CE were connected to an ammeter 25. In each of the photoelectric and thermoelectric sensors, the first region I was first illuminated by a light source (e.g. an LED, a laser, etc.). The second region II was then illuminated by the light source. Current flows generated by the photoelectric and thermoelectric sensor were measured by the ammeter 25 and were recorded.

Tables 2 and 3 show the maximum current flow for each of the photoelectric and thermoelectric sensors.

TABLE 2

| | Electrode Configuration | Current flow (μA) |
|---|---|---|
| Example 1 | Structure shown in | 1.2290 |
| | FIG. 4 | |
| Example 2 | Interdigitated | 0.7065 |
| | electrode structure with | |
| | 0.14 mm distance | |
| Example 3 | Interdigitated | 1.0912 |
| | electrode structure with | |
| | 0.6 mm distance | |

According to Table 2, each of the photoelectric and thermoelectric sensors 2 of E1 to E4 is capable of transforming light energy into electric energy. Based on the results of the Examples 2 and 3, the current flow increases with an increase in the distance between each of the first protruding portions 235 and an adjacent one of the second protruding portions 236.

TABLE 3

| | | | Current |
|---|---|---|---|
| | Electrode | Etching | flow |
| | Configuration | Solution | (μA) |
| Example 1 | Structure shown in | HF:IPA:DI | 1.2290 |
| | FIG. 4 | water = 1:3:1 | |
| Example 3 | Interdigitated | HF:IPA:DI | 1.0912 |
| | electrode | water = 1:3:1 | |
| | structure with 0.6 | | |
| | mm distance) | | |
| Example 4 | Interdigitated | HF:IPA:DI | 1.1160 |
| | electrode | water = 1:2:1 | |
| | structure with 0.6 | | |
| | mm distance) | | |
| Comparative | Interdigitated | HF:EtOH = 1:1 | 0.1110 |
| Example | electrode | | |
| | structure with 0.6 | | |
| | mm distance) | | |

As shown in Table 3, compared with the sensor of the Comparative Example, the photoelectric and thermoelectric sensors 2 manufactured by the method of this disclosure (i.e., the Examples 1, 3 and 4) generate higher current flows and have better photoelectric property.

To sum up, by virtue of the etching solution used in the electrochemically etching step, the photoelectric and thermoelectric sensors 2 exhibiting superior photoelectric and thermoelectric properties can be obtained. The conventional structure composed of N-type and P-type semiconductor elements can be omitted. The manufacturing process can be simplified and the cost thereof can be reduced.

While the disclosure has been described in connection with what are considered the embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method of manufacturing a photoelectric and thermoelectric sensor, comprising the steps of:
preparing a silicon substrate and an etching solution that includes hydrofluoric acid, isopropyl alcohol and deionized water;
performing electrochemical etching on the silicon substrate in the etching solution to obtain a porous silicon substrate; and
forming on the porous silicon substrate an electrode unit that is connected to the porous silicon substrate and that is adapted for being connected to an external circuit.

2. The method as claimed in claim 1, wherein a weight ratio of hydrofluoric acid to isopropyl alcohol to deionized water in the etching solution is 1:2:1 or 1:3:1.

3. The method as claimed in claim 1, wherein the electrochemical etching is conducted with an anode and a cathode, the anode is made of copper, and the cathode is made of platinum.

4. The method as claimed in claim 1, wherein the electrochemical etching is performed at a temperature ranging from 20° C. to 40° C. and a current density of 50 mA/cm² for 20 minutes to 40 minutes.

5. The method as claimed in claim 1, wherein the electrode unit is made of gold.

6. The method as claimed in claim 1, wherein the electrode unit includes a first electrode and a second electrode spaced apart from the first electrode.

7. The method as claimed in claim 1, wherein the electrode unit includes first and second electrodes, the first electrode having a first main portion and a plurality of first protruding portions extending from the first main portion, the second electrode having a second main portion spaced apart from the first main portion, and a plurality of second protruding portions extending from the second main portion, the first and second electrodes being arranged in an interdigitated comb structure.

8. A photoelectric and thermoelectric sensor comprising:
a porous silicon substrate; and
an electrode unit that is disposed on and connected to said porous silicon substrate, and that is adapted for being connected to an external circuit.

9. The photoelectric and thermoelectric sensor as claimed in claim 8, wherein said electrode unit is made of gold.

10. The photoelectric and thermoelectric sensor as claimed in claim 8, wherein said electrode unit includes a first electrode and a second electrode spaced apart from said first electrode.

11. The photoelectric and thermoelectric sensor as claimed in claim 8, wherein said electrode unit includes first and second electrodes, said first electrode having a first main portion and a plurality of first protruding portions extending from said first main portion, said second electrode having a second main portion spaced apart from said first main portion, and a plurality of second protruding portions extending from said second main portion, said first and second electrodes being arranged in an interdigitated comb structure.

12. The photoelectric and thermoelectric sensor as claimed in claim 8, wherein said porous silicon substrate is a p-type silicon substrate.

13. The photoelectric and thermoelectric sensor as claimed in claim 11, wherein a distance between one of said first protruding portions and an adjacent one of said second protruding portions is not greater than 0.6 mm.

14. A photoelectric and thermoelectric sensor obtained by the method of claim 1.
